(19) United States
(12) Patent Application Publication
(10) Pub. No.: US 2015/0076525 A1
(43) Pub. Date: Mar. 19, 2015

(54) LIGHT RECEIVING ELEMENT AND OPTICALLY COUPLED INSULATING DEVICE

(71) Applicant: Kabushiki Kaisha Toshiba, Tokyo (JP)

(72) Inventors: Miki Hidaka, Kanagawa-ken (JP); Toyoaki Uo, Fukuoka-ken (JP); Shigeyuki Sakura, Kanagawa-ken (JP)

(73) Assignee: Kabushiki Kaisha Toshiba, Tokyo (JP)

(21) Appl. No.: 14/202,424

(22) Filed: Mar. 10, 2014

(30) Foreign Application Priority Data
Sep. 13, 2013 (JP) 2013-191194

(51) Int. Cl. H01L 31/02; H01L 31/167

(52) U.S. Cl. CPC H01L 31/02005; H01L 31/167
USPC 257/82; 257/459

(57) ABSTRACT

A light receiving element includes: a semiconductor layer; a first layer; and a second layer. The semiconductor layer has a first impurity concentration. The first layer of a first conductivity type is provided inward from an upper surface of the semiconductor layer. The first layer has a second impurity concentration higher than the first impurity concentration. The first layer has a surface region on an upper surface of the semiconductor layer side and an inner region being narrower than the first region. The second layer of a second conductivity type is provided inward from the upper surface of the first semiconductor layer. The second layer has a third impurity concentration higher than the first impurity concentration.

### CROSS-REFERENCE TO RELATED APPLICATIONS

This application is based upon and claims the benefit of priority from Japanese Patent Application No. 2013-191194, filed on Sep. 13, 2013; the entire contents of which are incorporated herein by reference.

### FIELD

Embodiments described herein relate generally a light receiving element and an optically coupled insulating device.

### BACKGROUND

In many industrial electronic devices, communication devices, and the like, different power supply systems such as an AC power supply system, a DC power supply system, a telephone line system, etc., are disposed inside the same device to transmit an electrical signal.

In such a case, operations can be stable and safety can be ensured by using an optically coupled insulating device that can transmit the electrical signal in a state in which the input circuit and the output circuit are insulated from each other.

When a high voltage of 1 kV or more is applied between the input terminal and the output terminal of such an optically coupled insulating device, a noise component may occur in the light receiving element due to the electrostatic capacitance of an insulating layer between the input terminal and the output terminal.

The effects of such noise can be reduced by an electromagnetic shield structure in which the light receiving unit is covered with a conductive film, etc.; but problems such as an increase of the parasitic capacitance, a decrease of the response rate, etc., occur.

A light receiving element having reduced effects of the electromagnetic noise and a higher response rate is provided; and an optically coupled insulating device having reduced misoperations is provided.

### BRIEF DESCRIPTION OF THE DRAWINGS

FIG. 1A is a schematic plan view of a light receiving unit region of a light receiving element according to a first embodiment, and FIG. 1B is a schematic cross-sectional view along line A-A;

FIG. 2 is a schematic view showing a light receiving element according to a comparative example;

FIG. 3A is a schematic plan view of the light receiving unit region of a light receiving element according to a second embodiment, and FIG. 3B is a schematic cross-sectional view along line C-C;

FIG. 4 is a schematic plan view of the light receiving unit region of a light receiving element according to a third embodiment;

FIG. 5 is a schematic plan view of the light receiving unit region of a light receiving element according to a fourth embodiment;

FIG. 6 is a schematic cross-sectional view of an optically coupled insulating device including the light receiving element of the first to fourth embodiments; and

FIG. 7A is a schematic view showing a measurement system of the instantaneous common mode rejection voltage of the optically coupled insulating device, and FIG. 7B is a waveform diagram showing the change of the pulse voltage.

### DETAILED DESCRIPTION

In general, according to one embodiment, a light receiving element includes: a semiconductor layer; a first layer; and a second layer. The semiconductor layer has a first impurity concentration. The first layer of a first conductivity type is provided inward from an upper surface of the semiconductor layer. The first layer has a second impurity concentration higher than the first impurity concentration. The first layer has a surface region on an upper surface of the semiconductor layer side and an inner region being narrower than the first region. The second layer of a second conductivity type is provided inward from the upper surface of the first semiconductor layer. The second layer has a third impurity concentration higher than the first impurity concentration.

Embodiments of the invention will now be described with reference to the drawings.

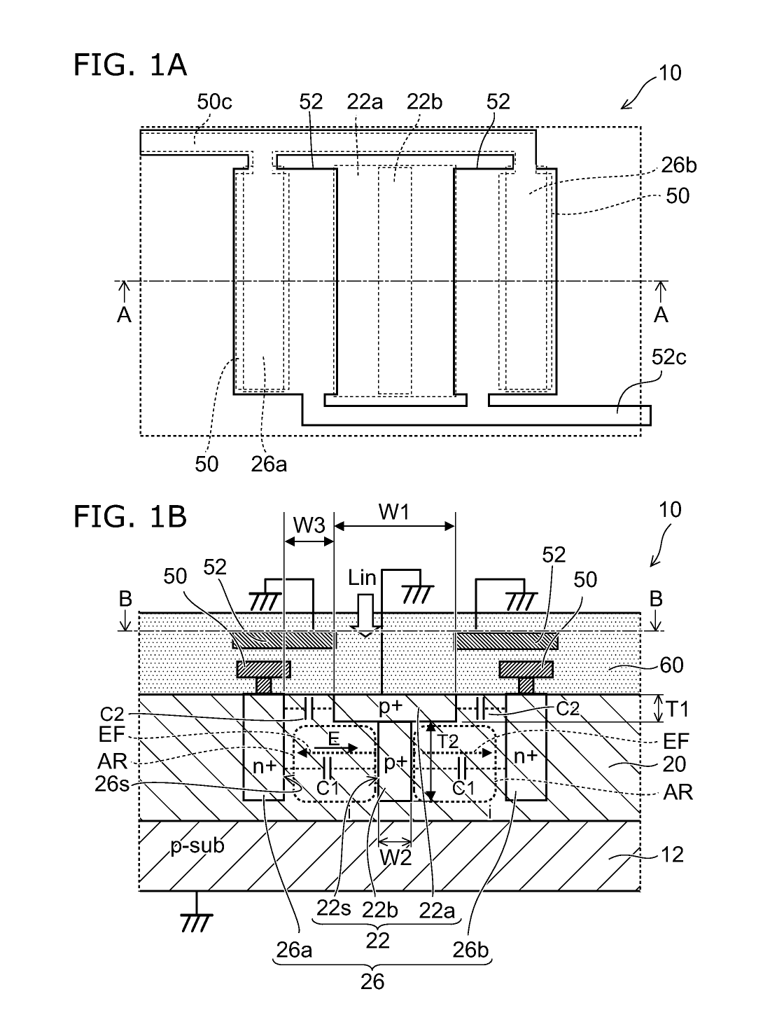

FIG. 1A is a schematic plan view of a light receiving unit region of a light receiving element according to a first embodiment; and FIG. 1B is a schematic cross-sectional view along line A-A.

The light receiving element 10 includes a substrate 12, a high-resistance semiconductor layer 20, a first layer 22, a second layer 26, an insulating layer 60, a metal interconnect layer 50, and a conductive film 52.

The substrate 12 is made of a semiconductor such as Si, etc., and has a first conductivity type. The high-resistance semiconductor layer 20 is provided on the substrate 12. A high quantum efficiency for near-infrared light (of a wavelength of 750 to 1000 nm) can be obtained by the high-resistance semiconductor layer 20 being made of Si. Also, a high quantum efficiency can be obtained for a wavelength of 1 μm to 1.5 μm by using a material such as Ge, InGaAsP, InGaAs, etc. In the specification, the resistivity (or the specific resistance) of the high-resistance semiconductor layer is set to be, for example, not less than 500 Ω·cm; and the conductivity type of the high-resistance semiconductor layer may be the p-type or the n-type.

The first layer 22 has the first conductivity type and is provided inside the high-resistance semiconductor layer 20. The first layer 22 may include a front surface region 22a, which is positioned on the front surface side and has a width W1 and a thickness T1, and an inner region 22b, which has a thickness T2 that is thicker than the thickness T1 of the front surface region 22a. Although the first layer 22 is provided not to reach the substrate 12 in FIG. 1B, the first layer 22 may reach the substrate 12.

The second layer 26 is provided inside the high-resistance semiconductor layer 20 without reaching the substrate 12, has a second conductivity type, and is disposed to be adjacent to the first layer 22 with the high-resistance semiconductor layer 20 interposed. The second layer 26 may have a first region 26a and a second region 26b that are provided on two sides of the first layer 22 in a first cross section orthogonal to the extension direction of the first layer 22. In the first cross section, the width W1 of the front surface region 22a is wider than a width W2 of the inner region 22b.

The high-resistance semiconductor layer 20 may be, for example, an epitaxial layer having a p-type impurity concentration of 1×10¹³ cm⁻³, etc. For example, the first layer 22 may have a p-type impurity concentration of 1×10¹⁸ cm⁻³, etc.; and the second layer 26 may have an n-type impurity concentration of 1×10¹⁸ cm⁻³, etc. The structures of the front surface region 22a and the inner region 22b of the first layer 22 are provided with the appropriate impurity concentrations and thicknesses (depths) by ion implantation of acceptors, etc.

The structure of the second layer 26 is provided with the appropriate impurity concentration and thickness (depth) by ion implantation of donors, etc. Although the first layer 22 is the p⁺-type and the second layer 26 is the n⁺-type in FIG. 1B, the conductivity types may be reversed. In such a case, the conductivity type of the substrate 12 also is reversed.

The insulating layer 60 is provided on the front surface of the high-resistance semiconductor layer 20, the front surface of the first layer 22, and the front surface of the second layer 26.

The insulating layer 60 may be a Si oxide film including SiOₓ, a Si nitride film including SiN_{y}, a low dielectric constant (low k) film, etc.

The metal interconnect layer 50 is connected to the front surface of the first region 26a and the front surface of the second region 26b; and the insulating layer 60 is filled between the metal interconnect layer 50 and the front surface of the high-resistance semiconductor layer 20.

The conductive film 52 is provided above the metal interconnect layer 50 to cover at least the metal interconnect layer 50 and the region (having a width W3) between the second layer 26 and the front surface region 22a of the first layer 22; and the insulating layer 60 is filled between the conductive film 52 and the front surface of the high-resistance semiconductor layer 20. The conductive film 52 may be connected to the first potential to have an electromagnetic shield effect. FIG. 1A is a schematic plan view looking downward along line B-B of the schematic cross-sectional view of FIG. 1B.

The metal interconnect layer 50 and the conductive film 52 may be Al, Cu, etc. The conductive film 52 may be a metal oxide such as ITO (Indium Tin Oxide), etc. The metal interconnect layer 50 may be connected to a circuit unit by a first draw-out portion 50c. The metal interconnect layer 50 and 50c are covered with the conductive film 52 and 52c. The conductive film 52 may be connected to a pad unit, etc., of the front surface of the chip by a second draw-out portion 52c.

The back surface of the substrate 12 and the front surface region 22a of the first layer 22 are set to have the first potential. Although the conductive film 52 may be set to have the first potential, the conductive film 52 may have another potential if the impedance is low. In FIGS. 1A and 1B, as described below in detail, the first potential may be, for example, the potential of a ground lead of the output leads of an optically coupled insulating device.

It is favorable for the width W1 of the front surface region 22a of the first layer 22 that is grounded to be wide because the noise from the outside can be blocked by electromagnetically shielding the interior of the light receiving element 10; and simultaneously, a light absorption region AR can be wider. On the other hand, the high-resistance semiconductor layer 20 between the inner region 22b and the second layer 26 can be wider and the volume of the light absorption region AR can be increased by setting the width W2 of the inner region 22b to be narrower than the width W1 of the front surface region 22a. A stray capacitance C2 can be reduced by increasing the width W3 between the second layer 26 and the front surface region 22a of the first layer 22. However, in the case where the width W3 is too wide, the light absorption region AR of the entire light receiving element 10 undesirably becomes narrow.

The photocurrent can be increased and the light reception sensitivity can be increased by generating electron-hole pairs in the interior of the light absorption region AR by the light irradiation. For example, it is favorable for the width of the front surface region 22a to be 5 to 30 μm, etc. It is favorable for the width W2 of the inner region 22b to be 1 to 10 μm, etc.

The electrons that are generated are caused to accelerate through the light absorption region AR by a lateral electric field E to reach the side surface of the second layer 26 opposing the side surface of the inner region 22b. The holes that are generated are caused to accelerate through the light absorption region AR by the lateral electric field E to reach either side surface of the first region 26a or the side surface of the second region 26b of the second layer 26. Thus, the light receiving element 10 of the embodiment has a lateral structure in which the carriers drift mainly due to a lateral electric field.

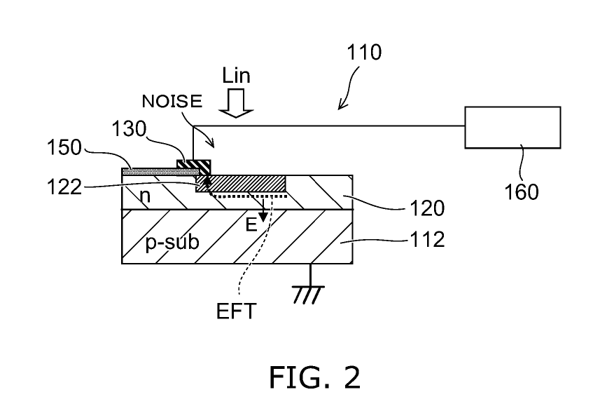

FIG. 2 is a schematic view showing a light receiving element according to a comparative example.

In the light receiving element 110 of the comparative example, an n-type layer 120 is provided on a p-substrate 112.

An n⁺-type layer 122 is provided on the n-type layer 120; and a cathode electrode 130 is connected to a portion of the front surface of the n⁺-type layer 122 with an insulating layer 150 interposed. In such a light receiving element 110, the back surface of the p-substrate 112 is grounded; and the cathode electrode 130 is connected to a signal processing circuit 160.

In the comparative example, an electromagnetic shield is not provided on the chip front surface side of the light receiving element 110. For example, a reverse bias of 5 V, etc., is supplied to the n-type layer 120; and the n-type layer 120 has a high impedance. Therefore, there are cases where the electromagnetic noise penetrates the interior of the light receiving element 110 and causes misoperations of the signal processing circuit 160.

The electrons and the holes drift mainly in a vertical direction perpendicular to the junction interface between the p-substrate 112 and the n-type layer 120. However, when an optical signal Lin is switched OFF, the stored electrons move (illustrated by an electron current EFT) in the horizontal direction along the junction interface by diffusion. The movement by diffusion is slower than the movement by drifting.

Therefore, it takes time to reach the cathode electrode 130; the pulse fall time is long; and the response rate decreases.

Conversely, in the light receiving element 10 of the first embodiment, the front surface region 22a of the first layer 22, the back surface of the substrate 12, and the conductive film 52 can be grounded. Also, the conductive film 52 can be provided at the upper portion of the metal interconnect layer 50 to electromagnetically shield the front surface of the high-resistance semiconductor layer 20. Thus, the penetration of the electromagnetic noise into the interior of the light receiving element 10 can be suppressed; and the misoperations can be reduced.

A p-n junction capacitance C1 of the light receiving element 10 can be reduced because the high-resistance semiconductor layer 20 is provided between a side surface 22s of the inner region 22b of the first layer 22 and a side surface 26s of the second layer 26. The parasitic capacitance can be reduced because an electromagnetic shield film such as a transparent conductive film, etc., is not provided above the first layer 22 which is used as the light receiving unit.

Further, even when the optical signal Lin is switched OFF, the electrons and the holes are accelerated by the electric field E to drift quickly in the electric field direction. Therefore, the movement of the carriers by diffusion is suppressed; the pulse fall time can be reduced; and it becomes easy to reduce the response time.

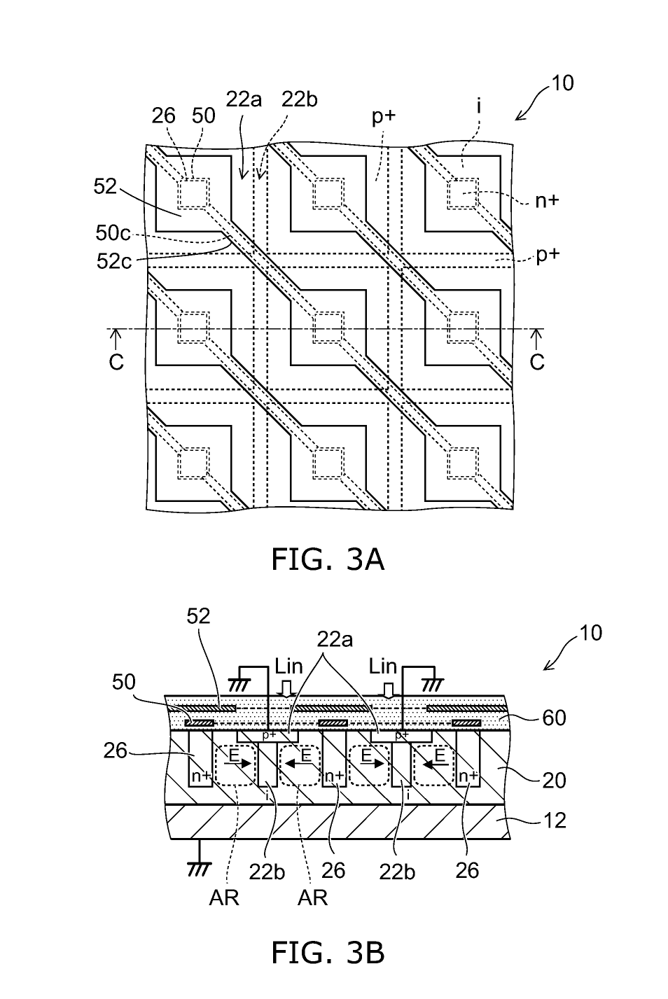

FIG. 3A is a schematic plan view of the light receiving unit region of a light receiving element according to a second embodiment; and FIG. 3B is a schematic cross-sectional view along line C-C.

The second layer 26 and the metal interconnect layer 50 each have multiple regions disposed two-dimensionally and regularly. In FIG. 3A, the multiple regions of the second layer 26 and the multiple regions of the metal interconnect layer 50 are squares or rectangles arranged in a lattice configuration. The first layer 22 is disposed at the center of two of the multiple regions of the second layer 26. Because the multiple regions are disposed two-dimensionally, the first layer 22 has, for example, a planar structure having a mesh configuration in which square and/or rectangular openings are provided such that the first layer 22 is provided around the multiple regions of the second layer 26.

The metal interconnect layer 50 has the first draw-out portion 50c connecting the multiple regions of the metal interconnect layer 50. The conductive film 52 has the second draw-out portion 52c connecting the multiple regions of the second draw-out portion 52c. To increase the surface area of the light absorption region AR, it is favorable for the first draw-out portion 50c and the second draw-out portion 52c to overlap as viewed from above.

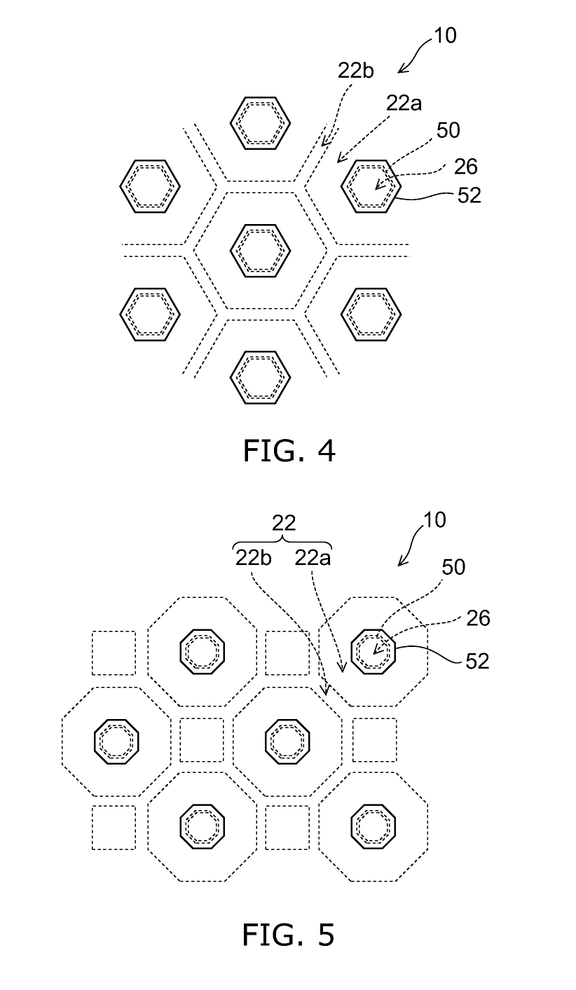

FIG. 4 is a schematic plan view of the light receiving unit region of a light receiving element according to a third embodiment.

The second layer 26 and the metal interconnect layer 50 each have multiple regions arranged two-dimensionally and regularly to maintain a prescribed spacing between the second layers 26 and between the metal interconnect layers 50. The first layer 22 has a honeycomb structure around the second layer 26 and the metal interconnect layer 50; the disposition can have a higher density than that of the planar disposition of the second embodiment; the surface area of the region shielded by the conductive film 52 is reduced; and the light reception sensitivity can be increased. The first and second draw-out portions are not shown.

FIG. 5 is a schematic plan view of the light receiving unit region of a light receiving element according to a fourth embodiment.

The inner region 22b (having the large thickness T2) of the first layer 22 is provided in an octagonal configuration around the second layer 26. In such a case, the distance between the side surface of the inner region 22b and the side surface of the second layer 26 can be more uniform than that of the second embodiment (the rectangular planar configuration) and the third embodiment (the honeycomb configuration). Therefore, the depletion layer in the horizontal direction spreads more uniformly; and the travel time of the carriers can be substantially the same. The light reception surface area can be increased further. The planar disposition is not limited to those of the embodiments. The first and second draw-out portions are not shown.

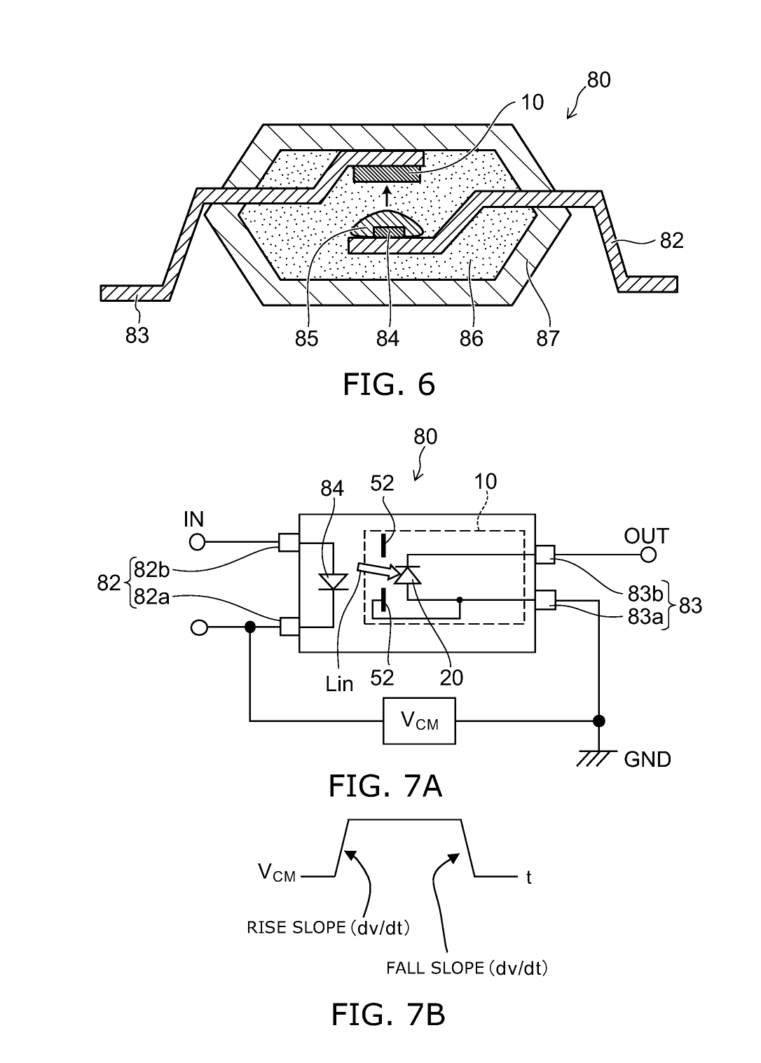

FIG. 6 is a schematic cross-sectional view of an optically coupled insulating device including the light receiving element of the first to fourth embodiments.

The optically coupled insulating device (including photocouplers and photorelays) 80 includes the light receiving element 10 of the first to fourth embodiments and a light emitting element 84 that irradiates near-infrared light toward the light receiving element 10. If the light receiving element 10 is provided on output leads 83 and the light emitting element 84 is provided on input leads 82, an inner resin layer 86 and an outer resin layer 87 may be further provided around the light emitting element 84 and the light receiving element 10 which oppose each other.

FIG. 7A is a schematic view showing a measurement system of the instantaneous common mode rejection voltage of the optically coupled insulating device; and FIG. 7B is a waveform diagram showing the change of the pulse voltage. In the optically coupled insulating device 80, the input leads 82 (the light emitting element 84 side) are insulated from the output leads 83 (the light receiving element 10 side). Therefore, there is a stray capacitance between the input leads 82 and the output leads 83.

When a pulse voltage V_{CM} that changes abruptly is applied to an input lead 82a, a displacement current flows; and noise that causes misoperations occurs in the output of the light receiving element 10. The instantaneous common mode rejection voltage can be expressed as the common mode noise immunity (CMR (Common Mode Rejection)). In other words, a high CMR means that the noise immunity is high.

The CMR is measured as the change of the output of the light receiving element 10 when the pulse voltage V_{CM} that changes abruptly is applied between the input lead 82a and an output lead 83a in a state in which a power supply voltage is supplied. In other words, the CMR is defined by the voltage slope (kV/μs) of the maximum pulse voltage V_{CM} for which the change of the output is not more than a prescribed value.

According to the embodiments, a light receiving element is provided in which the effects of the noise are reduced and the response rate is high. According to an optically coupled insulating device that includes such a light receiving element, for example, the CMR can be 10 kV/μs or more; and it is easy to suppress misoperations.

Such an optically coupled insulating device is used in industrial electronic devices, communication devices, etc., in which different power supply systems such as an AC power supply system, a DC power supply system, a telephone line system, etc., are disposed inside the same device. Therefore, the electrical signal can be transmitted safely while reducing misoperations.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A light receiving element, comprising:
a semiconductor layer having a first impurity concentration;
a first layer of a first conductivity type provided inward from an upper surface of the semiconductor layer, the first layer having a second impurity concentration higher than the first impurity concentration, the first layer having a surface region on an upper surface of the semiconductor layer side and an inner region being narrower than the first region; and
a second layer of a second conductivity type provided inward from the upper surface of the first semiconductor layer, the second layer having a third impurity concentration higher than the first impurity concentration.

2. The element according to claim 1, wherein
the second layer has a first region and a second region, and
the first layer is provided between the first region and the second region.

3. The element according to claim 1, wherein
the second layer has a plurality of regions disposed two-dimensionally and regularly, and
the first layer is provided around the plurality of regions of the second layer in a mesh configuration.

4. The element according to claim 1, further comprising:
a conductive film covering an entire upper surface of the second layer and an entire region of the upper surface of the semiconductor layer between an upper surface of the first layer and the surface of the upper surface of the second layer; and
an insulating layer provided between the semiconductor layer and the conductive film.

5. The element according to claim 4, further comprising:
a metal interconnect layer connecting to the second layer, provided between the semiconductor layer and the conductive film, and an entire upper surface of the metal interconnect layer covered with the conductive film.

6. The element according to claim 4, wherein
the second layer has a plurality of regions disposed two-dimensionally and regularly, and
the first layer is provided around the plurality of regions of the second layer in a mesh configuration.

7. The element according to claim 6, further comprising:
a metal interconnect layer connecting to the second layer, provided between the semiconductor layer and the conductive film, and having a first draw-out portion, and a plurality of regions connected by the first draw-out portion.

8. The element according to claim 7, wherein:
an entire upper surface of the metal interconnect layer is covered with the conductive film.

9. The element according to claim 7, wherein the conductive film has a second draw-out portion, and a plurality of regions connected by the second draw-out portion.

10. The element according to claim 9, wherein the first draw-out portion and the second draw-out portion extend to the same direction.

11. The element according to claim 4, wherein the conductive film and the first layer are connected to the first potential.

12. An optically coupled insulating device, comprising:
the light receiving element according to claim 1;
a light emitting element configured to irradiate light toward the light receiving element;
an output lead connecting to the light receiving element and including a ground lead; and
an input lead connecting to the light emitting element and insulated from the output lead.
